(19) United States
(12) Patent Application Publication
(10) Pub. No.: US 2010/0126547 A1
(43) Pub. Date: May 27, 2010

(54) Thermoelectric module

(76) Inventors: Gennadiy Gusamovich Gromov, Moscow (RU); Vasiliy Vasilievich Volodin, Moscow (RU)

Correspondence Address: MCDERMOTT WILL & EMERY LLP, 600 13TH STREET, N.W., WASHINGTON, DC, 20005-3096, US

(21) Appl. No.: 11/631,845

(22) PCT Filed: Apr. 25, 2005
(86) PCT No.: PCT/RU05/00222

§ 371 Date: Jul. 30, 2009

(30) Foreign Application Priority Data
Jul. 8, 2004 (RU) 2004120183

(51) Int. Cl. H01L 35/00

(52) U.S. Cl. 136/200

(57) ABSTRACT

The invention relates to microelectronic engineering, to the structural design of cooling thermoelectric modules in particular. The utility model can be used in single-cascade and multicascade thermoelectric modules. The aim of the invention is to provide a thermoelectric module design that absolutely excludes environmental factors. The invented thermoelectric module comprises at least one cascade of alternating n- and p-type thermoelectric elements (1), electrodes (2) connected to the thermoelectric elements (1), heat transfer substrates (5, 6) fixed on the heat-absorbing (3) and heat-rejecting ends (4) of the thermoelectric elements (1) by means of the electrodes, and an insulating film (7) continuously covering all the internal surfaces of the thermoelectric module.

The invention relates to microelectronic engineering, to the structural design of cooling thermoelectric modules in particular.

The invention suggested can be used in single-cascade and multicascade thermoelectric modules.

### Precedent Engineering Level

The design closest to the one suggested is a thermoelectric module comprising at least one cascade of alternating n- and p-type thermoelectric elements, electrodes connected to the thermoelectric elements, heat transfer substrates fixed on the heat-absorbing and heat-rejecting ends of the thermoelectric elements by means of the electrodes (see Patent RU 2178221, H01L35/32, 1999).

Each thermoelectric element side surface is covered by the insulating film of polyimide or poly—(substituted or non-substituted)—para-xylylene, which is deposited before the module is assembled. The process is laborious.

During the module assembling, while the thermoelectric elements are being soldered to the electrodes, the insulating film undergoes a considerable heating, which is detrimental to the film properties and the film itself.

There are gaps between thermoelectric elements.

In the described design the film improves the module strength and moisture resistance, prevents cracks and breaks as well as protects the free surfaces of the elements from corrosion in high moisture environment.

However in the said design there are parts of the module still exposed to aggressive environmental effects such as corrosion, destruction, electrical short-circuit. These parts are: the places of element-to-electrode soldering and leading wires attachment, the electrodes surface, and inner free surface of the heat-absorbing and heat-rejecting substrates.

As a result, a thermoelectric module device cannot operate in the high moisture conditions or an aggressive ambient.

### Invention Essentials

The aim of the invention is to provide a thermoelectric module design that absolutely excludes environmental factors.

The invented thermoelectric module comprises at least one cascade of alternating n- and p-type thermoelectric elements, electrodes connected to the thermoelectric elements, heat transfer substrates fixed on the heat-absorbing and heat-rejecting ends of the thermoelectric elements by means of the electrodes, and an insulating film continuously covering all the internal surfaces of the thermoelectric module.

The continuous insulating film of polyimide or poly—(substituted or non-substituted)—para-xylylene allows eliminating environmental influence, assures thermoelectric module operation in an aggressive ambient, provides higher reliability as well as strength and moisture resistance of the thermoelectric elements, prevents cracks and breaks in the thermoelectric elements when exposed to a mechanical impact or load and temperature stress.

The film thickness 1-20 μm is chosen according to technical requirements.

The tests proved that it is at these values of the film thickness that the film is technologically efficient enough.

In the design invented the continuous insulating film is deposited all over the internal surfaces of the module after it is completely assembled. The film covers the surfaces of the elements, the places of element-to-electrode soldering and leading wires attachment, the electrodes surfaces, inner free surface of the heat-absorbing and heat-rejecting substrates and the soldered ends of the leading wires.

During the patent studies no solutions identical to the one invented have been discovered, therefore the application for the patent corresponds to the criterion “novelty”.

We suppose that the information given in the application is sufficient for implementing the invention.

### FIGURE CAPTIONS AND GUIDANCE

The essence of the design suggested is described by the following figures and photographs.

FIG. 1 demonstrates a thermoelectric module;

FIG. 2 depicts a multicascade thermoelectric module;

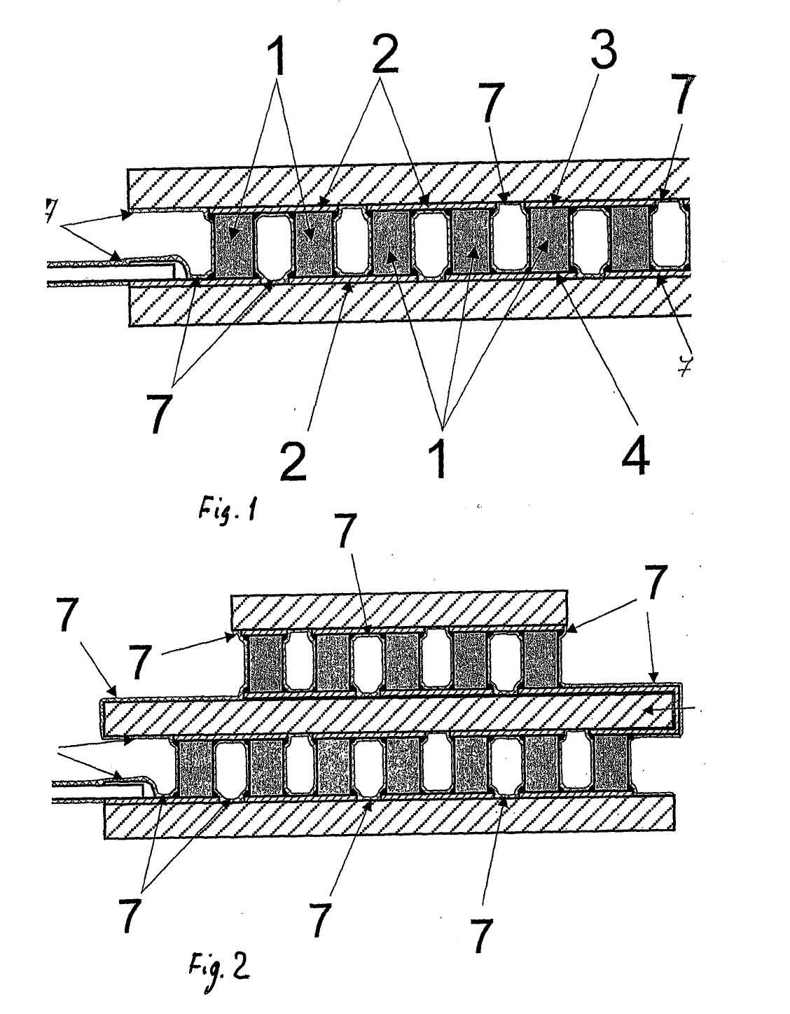

Photo 1 shows the results of comparison of a traditional and the suggested thermoelectric modules sunk in the saline bath;

Photo 2 yields a comparative picture of the exteriors of the two modules (with and without coating) after the testing in the saline bath, where a—the destruction of the thermoelectric elements surface; b—the corrosion of the metal surfaces (the places of element-to-electrode soldering and leading wires attachment, the electrodes surfaces).

### Implementation Best Example

The invented thermoelectric module comprises at least one cascade of alternating n- and p-type thermoelectric elements (1), electrodes (2) connected to the thermoelectric elements (1), heat transfer substrates (5, 6) fixed on the heat-absorbing (3) and heat-rejecting (4) ends of the thermoelectric elements (1) by means of the electrodes, and a continuous insulating film (7).

The film (7) covers all the internal surfaces of the thermoelectric module, including the surfaces of the thermoelectric elements (1), the places of element-to-electrode soldering (3,4) and leading wires (8) attachment, the electrodes surfaces (2), the inner surfaces of the plates (5,6) and the soldered ends of the leading wires (8).

The film material can be either polyimide or poly—(substituted or non-substituted)—para-xylylene.

A thermoelectric module can be of any cascades number (single-cascade or multicascade).

All the multicascade thermoelectric module internal surfaces such as the internal surfaces of each cascade (9), the surfaces of the inter-cascade substrates (10) have the all-over coating of the insulation films.

After the thermoelectric module assembling, all the surfaces are uniformly covered by the film with the help of any appropriate method such as polymerization with the chemical precipitation from vapor phase (see Patent RU #2178221, H01L35/32).

The module invented is operated as follows.

When exposed to DC electric current, the thermoelectric module undergoes the Peltier effect.

If the module operates in any aggressive or electroconductive environment (vapor, gas, liquid), it remains serviceable.

Moreover, the continuous insulating film improves the mechanical strength of the module: prevents any cracking or splitting of the thermoelectric elements, breaking of the elements from the electrodes, detaching of electrodes from the substrates.

Thus the module reliability and life are improved.

Besides, a film coating of all the thermoelectric module internal surfaces has an advantage over the precedent method for higher adaptability to manufacture, reliability and simplicity.

### INDUSTRIAL APPLICABILITY

The invented thermoelectric module prototype was produced and tested. The traditional and the suggested thermoelectric modules were sunk into the 10% NaCl solution and electric current was switched on in both the modules. Due to electrical conductivity and aggressiveness of the saline environment, the traditional module was quickly destroyed (the darkened solution is the evidence of the electrolysis products desorption) and very soon the device underwent open circuit and was out of service. At the same time the invented design module continued working (photo 1).

The invented module properties did not degrade or the module was not injured in any way. The traditional design bore evidence of destruction due to the electrolysis and interaction with the aggressive environment: destruction of the thermoelectric elements (a), metal surfaces corrosion (b)—in the places of element-to-electrode soldering and leading wires attachment (photo 2).

1. A thermoelectric module comprising at least one cascade of alternating n- and p-type thermoelectric elements (1), electrodes (2) connected to the thermoelectric elements (1), heat transfer substrates (5, 6) fixed on the heat-absorbing (3) and heat-rejecting (4) ends of the thermoelectric elements (1) by means of the electrodes, and characterized by an insulating film (7) continuously covering all the internal surfaces of the thermoelectric module.

2. The thermoelectric module of item 1 characterized that the thin isolation film (7) is made of polyimide or poly—(substituted or non-substituted)—para-xylene.

3. The thermoelectric module of items 1 or 2 characterized that the isolation film has thickness in the range of 1 to 20 μm.
